(19) United States
(12) Patent Application Publication
(10) Pub. No.: US 2009/0115715 A1
(43) Pub. Date: May 7, 2009

(54) LIQUID CRYSTAL DISPLAY SOURCE DRIVER INTEGRATED CIRCUIT

(76) Inventors: Peter H. Xiao, Belmont, CA (US); Chih-Wen Lu, Jhumen Village (TW)

Correspondence Address: Nixon Peabody LLP, 200 Page Mill Road, Suite 200, Palo Alto, CA, 94306, US

(21) Appl. No.: 11/936,092

(22) Filed: Nov. 7, 2007

(51) Int. Cl. G09G 3/18; H03L 5/00

(52) U.S. Cl. 345/98; 327/306

(57) ABSTRACT

A source driver eliminates the need for a level shifter and enables the use of a low voltage digital-to-analog converter by using an operational buffer that performs voltage amplification in addition to driving a TFT panel.

### TECHNICAL FIELD

This invention relates generally to liquid crystal displays (LCDs), and more particularly, but not exclusively, provides a source driver integrated circuit for use in a liquid crystal display.

### BACKGROUND

LCD source drivers (also referred to as column drivers) are a critical component in the LCD application. Source drivers supply video data signals to data lines connected to the source of Thin Film Transistors (TFTs) at each pixel of an LCD. A good LCD driver design is crucial. In the conventional LCD source driver approach, as shown in FIG. 1, the input digital data is latched into a data latch 105. Through a voltage level shifter 120, the digital data is shifted to a high voltage level. Then it goes through a digital-to-analog converter (DAC) 130 to generate a high voltage analog signal level. This signal then drives an operational buffer 135 towards a TFT LCD panel 140.

In this conventional approach, the digital-to-analog conversion is accomplished with high voltage devices. Usually the high voltage semiconductor devices are area consuming and take up much silicon area, thereby increasing cost and limiting area for other components.

As such, a new source driver is needed that consumes less area.

### SUMMARY

Embodiments of the invention provide a source driver that eliminates the need for a level shifter and enables the use of a low voltage digital-to-analog converter by using an operational buffer that performs voltage amplification in addition to driving a TFT panel. As such, complexity and area is reduced, thereby reducing costs.

In an embodiment, the operational buffer comprises a transistor, a feedback capacitor and an input capacitor. The transistor has two voltage inputs and one voltage output. A first voltage input receives an input voltage and a second voltage input receives a reference voltage. The feedback capacitor has a capacitance C and is coupled to the voltage output and the first voltage input. The input capacitor has a capacitance equal to a multiple of the capacitance of the feedback capacitor and is coupled to the first voltage input.

In an embodiment of the invention, the source driver includes a latch that receives digital data, a digital-to-analog converter coupled to the latch that converts the digital data to analog data (voltage), and one or more operational buffers coupled to the digital-to-analog converter that amplifies the voltage and drives a TFT.

In an embodiment of the invention, a method of driving a TFT comprises receiving digital data; converting the digital data to voltage; amplifying the voltage using an operational buffer; and driving a TFT with the amplified voltage.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating a conventional LCD;

FIG. 2 is a block diagram illustrating a LCD according to an embodiment of the invention;

FIG. 3 is a block diagram illustrating an operational buffer of the source driver of FIG. 2; and

FIG. 4 is a flowchart illustrating a method of using the source driver of FIG. 2.

### DETAILED DESCRIPTION OF THE ILLUSTRATED EMBODIMENTS

The following description is provided to enable any person having ordinary skill in the art to make and use the invention, and is provided in the context of a particular application and its requirements. Various modifications to the embodiments will be readily apparent to those skilled in the art, and the principles defined herein may be applied to other embodiments and applications without departing from the spirit and scope of the invention. Thus, the present invention is not intended to be limited to the embodiments shown, but is to be accorded the widest scope consistent with the principles, features and teachings disclosed herein.

FIG. 2 is a block diagram illustrating an LCD 200 according to an embodiment of the invention. The LCD 200 comprises a source driver 205 coupled to a TFT panel 140. For ease of illustration, other components of the LCD 200 (e.g., a gate driver) that are not relevant are not shown. The source driver 205 includes a latch 110 coupled to a DAC 230, which is coupled to a plurality of operational buffers 235. While four operational buffers 235 are illustrated, it will be appreciated by one of ordinary skill in the art that the source driver 205 can include many more operational buffers 235 (e.g., 384 buffers 235).

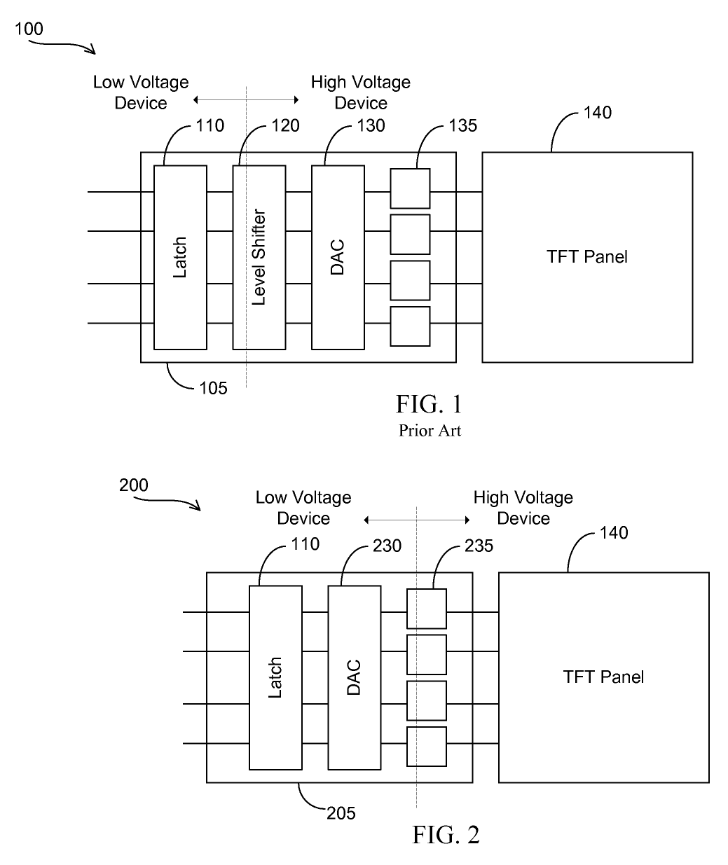

Embodiments of the invention partition the functional blocks of the source driver 205 differently than the conventional source driver 105 (FIG. 1). Low voltage to high voltage conversion is accomplished in the final Operational Buffer 235 instead of by the level shifter 120. Instead of unit gain buffering that the conventional operational buffer 135 does, the Operational Buffer 235 needs to provide N times gain in addition to the buffering function. All the blocks before the buffer 235 become low voltage devices, thereby reducing complexity and area required. The DAC 230 comprises low voltage device now and saves silicon area. The digital level shifter 120 can be omitted to save silicon area further as the operation buffer 235 performs the amplification, as described further below.

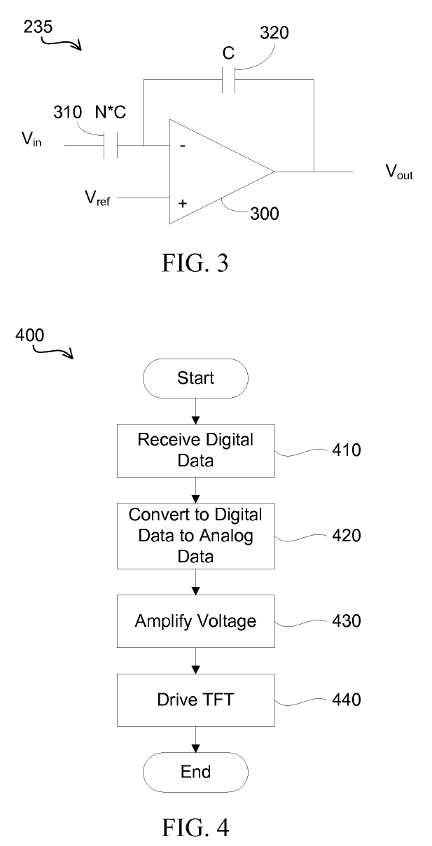

FIG. 3 is a block diagram illustrating the operational buffer 235 of the source driver 205. The operation buffer 235 comprises a transistor 300 with two voltage inputs (Vᵢₙ, and V_{ref}) and one voltage output (Vₒᵤₜ). Coupled to Vᵢₙ is an input capacitor 310. Coupled between Vᵢₙ and Vₒᵤₜ is a feedback capacitor 320. The feedback capacitor has a capacitance C and while the input capacitor 310 has a capacitance of N*C.

Accordingly, the relation of output voltage to input voltage can be described as:

Vₒᵤₜ=V_{ref}+N*(Vᵢₙ−V_{ref}) Equation 1

Output voltage is amplified N times from the input voltage, where V_{ref} is a reference voltage can be chosen to achieve the desired output voltage level.

FIG. 4 is a flowchart illustrating a method 400 of using the source driver 205 (FIG. 2). First, the latch 110 receives (410) digital data. The DAC 230 then converts (230) the digital data to analog data (i.e., voltage). The operational buffers 235 then amplify (430) the voltage and drive (440) the TFT panel 140. The method 400 then ends.

The foregoing description of the illustrated embodiments of the present invention is by way of example only, and other variations and modifications of the above-described embodiments and methods are possible in light of the foregoing teaching. For example, the operation buffers 235 can be used in a gate driver IC or for other applications besides LCDs. Further, components of this invention may be implemented using a programmed general purpose digital computer, using application specific integrated circuits, or using a network of interconnected conventional components and circuits. Connections may be wired, wireless, modem, etc. The embodiments described herein are not intended to be exhaustive or limiting. The present invention is limited only by the following claims.

What is claimed is:

1. An operational buffer, comprising:
a transistor having two voltage inputs and one voltage output, wherein a first voltage input receives an input voltage and a second voltage input receives a reference voltage;
a feedback capacitor having a capacitance C, the feedback capacitor coupled to the voltage output and the first voltage input; and
an input capacitor having a capacitance equal to a multiple of the capacitance of the feedback capacitor, the input capacitor coupled to the first voltage input.

2. The operational buffer of claim 1, wherein the first voltage input receives a voltage from a digital-to-analog converter.

3. The operational buffer of claim 1, wherein the buffer amplifies an input voltage by the multiple.

4. The operational buffer of claim 1, wherein the output from the voltage output drives a TFT.

5. A source driver for an LCD, comprising:
a latch;
a digital-to-analog converter coupled to the latch, and
a operational buffer coupled to the digital-to-analog converter;
the operational buffer comprising
a transistor having two voltage inputs and one voltage output, wherein a first voltage input receives an input voltage and a second voltage input receives a reference voltage;
a feedback capacitor having a capacitance C, the feedback capacitor coupled to the voltage output and the first voltage input; and
an input capacitor having a capacitance equal to a multiple of the capacitance of the feedback capacitor, the input capacitor coupled to the first voltage input.

6. The source driver of claim 5, wherein the first voltage input receives a voltage from the digital-to-analog converter.

7. The source driver of claim 5, wherein the buffer amplifies an input voltage by the multiple.

8. The source driver of claim 5, wherein the output from the voltage output drives a TFT.

9. The source driver of claim 5, wherein the latch and the digital-to-analog converter operate at a lower voltage than the operational buffer.

10. The source driver of claim 5, further comprising a plurality of operational buffers coupled to the digital-to-analog converter.

11. A method of driving a TFT, comprising:
receiving digital data;
converting the digital data to voltage;
amplifying the voltage using an operational buffer; and
driving a TFT with the amplified voltage.

12. The method of claim 11, wherein the operational buffer comprises:
a transistor having two voltage inputs and one voltage output, wherein a first voltage input receives an input voltage and a second voltage input receives a reference voltage;
a feedback capacitor having a capacitance C, the feedback capacitor coupled to the voltage output and the first voltage input; and
an input capacitor having a capacitance equal to a multiple of the capacitance of the feedback capacitor, the input capacitor coupled to the first voltage input.

13. The method of claim 12, wherein the first voltage input receives a voltage from a digital-to-analog converter that performs the converting.

14. The method of claim 12, wherein the buffer amplifies an input voltage by the multiple.

15. The method of claim 12, wherein a latch performs the receiving and a digital-to-analog converter performs the converting, and wherein the latch and the digital-to-analog converter operate at a lower voltage than the operational buffer.
